(19) United States
(12) Patent Application Publication
(10) Pub. No.: US 2007/0109761 A1
(43) Pub. Date: May 17, 2007

(54) Power-source switch box with a stabilizer

(75) Inventor: Huo-Tu Huang, Taipei Hsien (TW)

Correspondence Address: BACON & THOMAS, PLLC, 625 SLATERS LANE, FOURTH FLOOR, ALEXANDRIA, VA, 22314, US

(73) Assignee: Huangslite Industrial Co., Ltd., Taipei Hsien (TW)

(21) Appl. No.: 11/274,408

(22) Filed: Nov. 16, 2005

(51) Int. Cl. H05K 7/00

(52) U.S. Cl. 361/837

(57) ABSTRACT

A power-source switch box with a stabilizer, it mainly has a control circuit board in its main body; the control circuit board is provided thereon with a stabilizer and a switch of a power source, the two ends of it are connected with lines respectively at an output terminal and an input terminal of the power source, by turning on/off of the switch of the power source on the main body, the power source provides stable power through the stabilizer for a lamp. When the power source is turned off, the power is cut and renders the stabilizer and the lamp to stop working; thereby the situation that the stabilizer continues to work after the lamp is not in use can be avoided, and thereby the life of use of the lamp can be largely increased.

### BACKGROUND OF THE INVENTION

1. Field of the Invention

The present invention is related to a power-source switch box with a stabilizer, and especially to a power-source switch box that can control the stabilizer therein is for operating or not operating and thereby can largely increase the life of use of the power-source switch box, the power-source switch box particularly suits a desk lamp using a fluorescent lamp for illumination.

2. Description of the Prior Art

A very large part of necessities in our lives used nowadays include light source in addition to water and electricity, hence light emitting elements of the class of fluorescent lamps such as sun lamps and power saving lamp bulbs etc. have been thought highly of from day to day; and in view of this, manufacturers try hard to study how to increase the effect of light emitting of these lamps and to provide products having their life of use increased.

In turning on of a conventional fluorescent lamp, a starter shall be provided in addition to the requirement of an electromagnetic stabilizer, in order that the starter can ignite a lamp pipe. A conventional stabilizer has a certain range of working frequency, e.g. 50/60 Hz, this renders the fluorescent lamp to have a phenomenon of flashing, and indirectly makes the ratio of near sight overly high. If an electronic stabilizer of high frequency is used instead, the phenomenon of flashing of a lamp pipe can be reduced, not only fatigue of eyes can be reduced, but also the ratio of near sight of children students can be largely reduced.

And more, the material structure of a conventional stabilizer contains a large amount of copper wires and silicon steel sheets, it appears cumbersome by volume; besides relatively, it consumes electricity about 30% more than that of an electronic stabilizer; and because of bad processing, it generates serious buzzing forming noise.

It can be seen from the above stated that, stabilizers occupy a very important position in using lamps, especially desk lamps which are nearer to eyes; the importance of the stabilizers is evident. Various desk lamps used presently have the stabilizers provided each on a lamp shade or a lamp receptacle, this renders the designing of the desk lamps limited, and when the power source for a desk lamp is turned off, the stabilizer of the lamp goes on working, hence the life of use of the stabilizer is largely decreased; and thereby it is an important subject to know how to avoid continuous working of a stabilizer after turning off of the power source.

Accordingly, the above stated conventional lamps still are defective and are not well designed, improvement thus is necessary.

The inventor of the present invention tried hard to make improvement and innovation in view of the above defects of the conventional lamps, and lastly developed a power-source switch box with a stabilizer of the present invention after hard study for years.

### SUMMARY OF THE INVENTION

The present invention aims at getting the object of the invention of providing a power-source switch box with a stabilizer, it mainly has a control circuit board in its main body; the control circuit board is provided thereon with a stabilizer and a switch of the power source, the two ends of it are connected with lines respectively at an output terminal and an input terminal of the power source, by turning on/off of the switch of the power source on the main body, the power source provides stable power through the stabilizer for a lamp. When the power source is turned off, the power is cut and renders the stabilizer and the lamp to stop working; thereby the situation that the stabilizer continues to work after the lamp is not in use can be avoided, and thereby the life of use of the lamp can be largely increased.

The output terminal of the power source of the abovementioned circuit board is connected with a connector firmly engaged in the front end of the main body, it is connected with the lamp and has a mutual controlling function with latter via an output power-source line. The input terminal of the power source is fixedly engaged with the main body through a positioning member, and then is connected with an input power-source line, so that the power-source lines at the two ends of the main body is not subjected to damage by tearing.

And more, the main body is composed of an upper housing and a lower housing to form therein a receiving space for receiving the control circuit board and its related elements. The upper housing has a positioning hole for slipping and connecting therein the switch of a power source which can be exposed out of the main body for use.

When in practicing, the connector is composed of a female socket, a male plug and a cover; wherein the female socket is engaged in the main body at the output terminal of the power source, and is connected with the switch of the power source through a power-source line; the female socket is connected by means of the male plug and is connected with the lamp via a power source line, in this way, the female socket, the male plug and the switch of the power source get the effect of electrically connecting. The outer wall of the male plug is screw connected with the female socket by means of the cover; thereby the power source line is not subjected to damage by tearing.

When in use, the switch of the power source on the main body controls turning on/off of the lamp, when the switch of the power source is turned off, electric power is not supplied, and the stabilizer stops working, this can largely increase the life of use of the lamp.

The object of the present invention is to provide a power-source switch box with a stabilizer, in which by combination of the switch of the power source with the stabilizer, the stabilizer can be controlled to avoid continuous working of the stabilizer after turning off of the power source, this can largely increase the life of use of the lamp.

Another object of the present invention is to provide a power-source switch box with a stabilizer, in which a connector is provided at the output terminal of the power source on the main body, the connector has a cable connecting to the lamp, thereby the power-source switch box with the stabilizer is not subjected to damage by pulling of the connector during pulling the cable.

A further object of the present invention is to combine the stabilizer with the switch of the power source in order that designing of the lamp is not limited, and thereby the product of lamp can be artistic, and its volume can be diminished.

The present invention will be apparent in its content and effect to be achieved after reading the detailed description of the preferred embodiment thereof in reference to the accompanying drawings.

### BRIEF DESCRIPTION OF THE DRAWINGS

FIG. 1 is an anatomic perspective view of a power-source switch box with a stabilizer of the present invention;

FIG. 2 is a perspective view of the power-source switch box with the stabilizer of the present invention after assembling;

FIG. 3 is an exploded perspective schematic view of the power-source switch box with the stabilizer of the present invention;

FIG. 4 is a perspective schematic view showing use of the power-source switch box with the stabilizer of the present invention.

### DETAILED DESCRIPTION OF THE PREFERRED EMBODIMENT

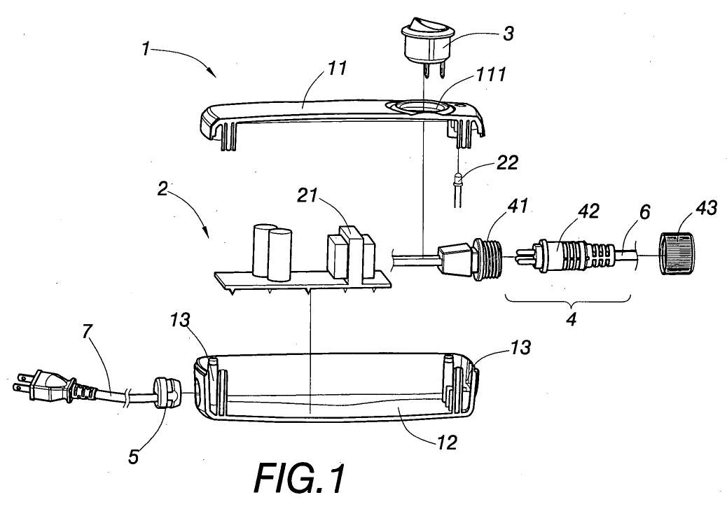

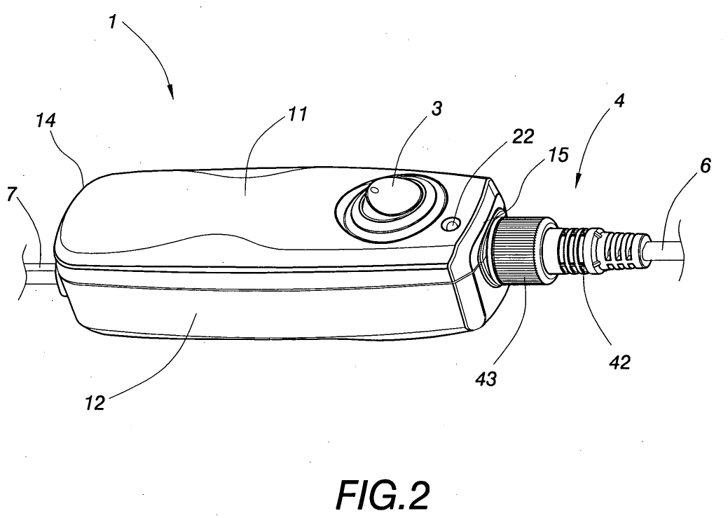

Referring firstly to FIG. 1 showing an anatomic perspective view of the power-source switch box with the stabilizer of the present invention, the power-source switch box mainly comprises: a main body 1, a control circuit board 2, a connector 4 and a positioning member 5; while FIG. 2 depicts a perspective view after assembling.

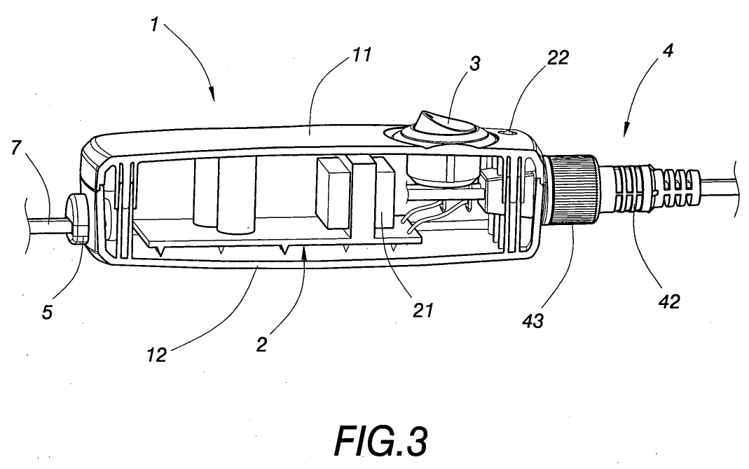

Referring simultaneously to FIGS. 1 and 3, the main body 1 is composed of an upper housing 11 and a lower housing 12 engaging with each other to form in the main body 1 a receiving space for receiving a control circuit board 2 and its related elements; the upper housing 11 has on its top a positioning hole 111 for slipping and connecting therein a switch 3 of the power source which can be exposed out of the upper surface of the main body 1 for use; the main body 1 has on each of its two ends an engaging cut 13 for engaging a connector 4 and a positioning member 5 in use, thus the main body 1 further has an input terminal 14 and an output terminal 15 of the power source.

The control circuit board 2 is received in the main body 1, it is provided thereon with a stabilizer 21 and the switch 3 of the power source, the switch 3 controls turning on/off of the power source, when the power source is turned off, the power source is no more input to the stabilizer 21; and in practicing, the circuit board 2 can be provided thereon with a light emitting member 22 such as an LED, so that turning on of the power source can be displayed with the light emitting member 22.

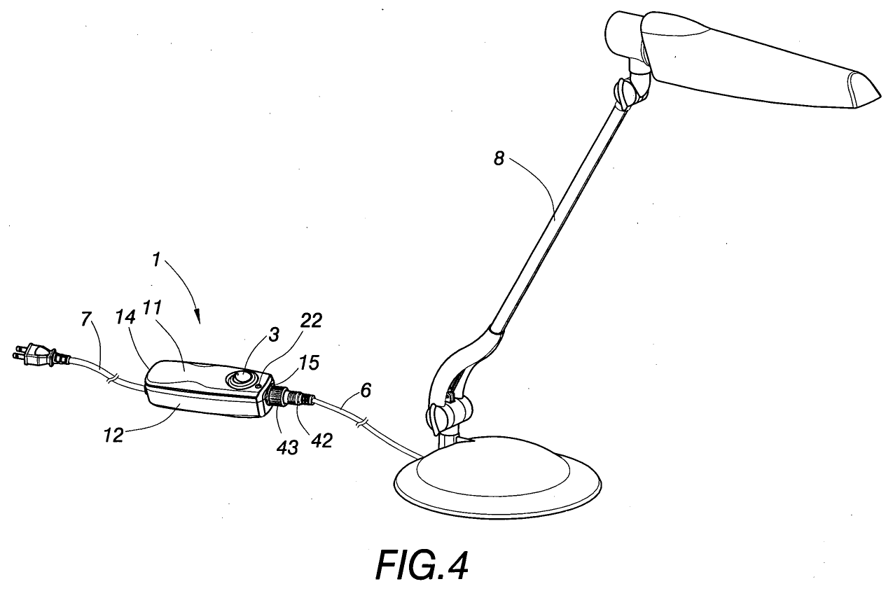

The connector 4 is composed of a female socket 41, a male plug 42 and a cover 43, wherein the female socket 41 is engaged in one of the engaging cuts 13 at the output terminal 15 of the power source, and is connected with the switch 3 of the power source through a power source line; the female socket 41 is connected by means of the male plug 42 and is connected with a lamp 8 via a power source line 6 (referring simultaneously to FIG. 1 and FIG. 4), in this way, the female socket 41, the male plug 42 and the switch 3 of the power source get the effect of electrically connecting; the outer wall of the male plug 42 is screw connected with the female socket 41 by means of the cover 43; thereby the power source line 6 is not subjected to damage by tearing.

The positioning member 5 is engaged in the engaging cut 13 at the input terminal 14 of the power source on the main body 1, and is connected with a power source line 7, thereby the power can get in the main body 1, and thereby the power source line 7 is not subjected to damage by tearing.

When in use, the switch 3 of the power source is used to control turning on/off of the lamp 8, when the switch 3 is turned off, electric power is cut, and the power is no more input to the stabilizer 21, the lamp 8 stops working; thereby the situation that the stabilizer 21 continues to work after the lamp 8 is not in use can be avoided, and thereby the life of use of the lamp can be largely increased. Moreover, the stabilizer 21 and the switch 3 of the power source are provided on the main body 1, thereby the lamp shade and the lamp receptacle of the lamp 8 are not limited by the stabilizer 21 and the switch 3 of the power source, the volume of the lamp shade and the lamp receptacle can be largely reduced, and thereby an object that the product of lamp is made artistic can be achieved.

The embodiment given is only for illustrating the present invention, and not for giving any limitation to the scope of the present invention. It will be apparent to those skilled in this art that various equivalent modifications or changes without departing from the spirit of this invention shall also fall within the scope of the appended claims.

1. A power-source switch box with a stabilizer, said switch box has a control circuit board in its main body; said control circuit board is provided thereon with a stabilizer and a switch of said power source, the two ends of it are connected with lines respectively at an output terminal and an input terminal of said power source; when said power source is turned off, power stops to input to said stabilizer.

2. A power-source switch box with a stabilizer as in claim 1, wherein: said main body is composed of an upper housing and a lower housing engaging with each other to form therein a receiving space, said main body has on each of its two ends an engaging cut.

3. A power-source switch box with a stabilizer as in claim 1, wherein: said output terminal of said power source is connected with a connector firmly engaged in a front end of said main body, and is connected with a lamp and has a mutual controlling function with said lamp via an output power-source line.

4. A power-source switch box with a stabilizer as in claim 1, wherein: said input terminal of said power source is fixedly engaged with said main body through a positioning member, and then is connected with an input power-source line.

5. A power-source switch box with a stabilizer as in claim 3, wherein: said connector is composed of a female socket, a male plug and a cover; and wherein said female socket is engaged in said main body at said output terminal of said power source, and is connected with said switch of said power source through said input power-source line; said female socket is connected by means of said male plug and is connected with said lamp via said output power-source line, an outer wall of said male plug is screw connected with said female socket by means of said cover.

6. A power-source switch box with a stabilizer as in claim 1, wherein: said circuit board is provided thereon with a light emitting member.

7. A power-source switch box with a stabilizer as in claim 6, wherein: said light emitting member is an LED.
